(19) United States
(12) Patent Application Publication
(10) Pub. No.: US 2026/0171141 A1
(43) Pub. Date: Jun. 18, 2026

(54) SEMICONDUCTOR MEMORY DEVICE INCLUDING SUB WORD-LINE DECODER UNDER MEMORY CELL ARRAY AND MEMORY PACKAGE INCLUDING THE SAME

(71) Applicant: Samsung Electronics Co., Ltd., Suwon-si (KR)

(72) Inventors: Sanghoon Jung, Suwon-si (KR); Younghun Seo, Suwon-si (KR); Hyunchul Yoon, Suwon-si (KR)

(21) Appl. No.: 19/267,304

(22) Filed: Jul. 11, 2025

(30) Foreign Application Priority Data
Dec. 17, 2024 (KR) 10-2024-0187933

(51) Int. Cl. G11C 11/408; G11C 11/4091

(52) U.S. Cl. CPC G11C 11/4085; G11C 11/4087; G11C 11/4091

(57) ABSTRACT

An example semiconductor memory device includes a first semiconductor layer and a second semiconductor layer. The first semiconductor layer includes a memory cell array. The memory cell array includes memory cells to store data. The second semiconductor layer is under the first semiconductor layer and includes a peripheral circuit to control the memory cell array. The peripheral circuit includes one or more sub word-line drivers and a sub word-line decoder. The one or more sub word-line drivers drive word-lines. The sub word-line decoder applies a word-line enable signal to the one or more sub word-line drivers based on a first intermediate word-line enable signal and a second intermediate word-line enable signal. A region in which the one or more sub word-line drivers and the sub word-line in the second semiconductor layer is under a region in which the plurality of memory cells are in the first semiconductor layer.

### CROSS-REFERENCE TO RELATED APPLICATION

This application claims priority under 35 USC § 119 to Korean Patent Application No. 10-2024-0187933 filed on Dec. 17, 2024 in the Korean Intellectual Property Office (KIPO), the content of which is incorporated herein by reference in its entirety.

### BACKGROUND

Semiconductor memory devices may be divided into two categories depending upon whether or not they retain stored data when disconnected from a power supply. These categories include volatile memory devices, which lose stored data when disconnected from power, and nonvolatile memory devices, which retain stored data when disconnected from power.

Various structures are being adopted to increase the integration degree of memory devices and reduce the size of memory devices. However, the reduction of the size of memory devices is limited because the memory device should still include a peripheral circuit for driving a memory cell array and a wiring structure to electrically connect the memory cell array with the peripheral circuit. Recently, methods are used in which elements included in the memory device are fabricated on separate wafers, rather than being fabricated on a single wafer, and then bonded to each other.

### SUMMARY

The present disclosure relates to a semiconductor memory device capable of efficiently reducing size and enhancing performance, and a memory package including the semiconductor memory device.

In general, according to some aspects, a semiconductor memory device includes a first semiconductor layer and a second semiconductor layer. The first semiconductor layer includes a memory cell array connected to a plurality of word-lines and a plurality of bit-lines. The memory cell array includes a plurality of memory cells to store data, the plurality of word-lines extend in a first direction and the plurality of bit-lines extend in a second direction crossing the first direction. The second semiconductor layer is under the first semiconductor layer in a third direction perpendicular to both the first direction and the second direction and includes a peripheral circuit to control the memory cell array. The peripheral circuit includes one or more sub word-line drivers and a sub word-line decoder. The one or more sub word-line drivers drive the plurality of word-lines. The sub word-line decoder applies a word-line enable signal to the one or more sub word-line drivers based on a first intermediate word-line enable signal and a second intermediate word-line enable signal. A first region in which the one or more sub word-line drivers and the sub word-line decoder are in the second semiconductor layer is under a memory region in which the plurality of memory cells are in the first semiconductor layer in a plan view.

In general, according to some aspects, a memory package includes a base substrate and a plurality of memory chips stacked on the base substrate. Each of the plurality of memory chips includes a first semiconductor layer and a second semiconductor layer. The first semiconductor layer includes a memory cell array connected to a plurality of word-lines and a plurality of bit-lines. The memory cell array includes a plurality of memory cells to store data, the plurality of word-lines extend in a first direction and the plurality of bit-lines extend in a second direction crossing the first direction. The second semiconductor layer is under the first semiconductor layer in a third direction perpendicular to both the first direction and the second direction and includes a peripheral circuit to control the memory cell array. The peripheral circuit includes one or more sub word-line drivers and a sub word-line decoder. The one or more sub word-line drivers drive the plurality of word-lines. The sub word-line decoder applies a word-line enable signal to the one or more sub word-line drivers based on a first intermediate word-line enable signal and a second intermediate word-line enable signal. A first region in which the one or more sub word-line drivers and the sub word-line decoder are in the second semiconductor layer is under a memory region in which the plurality of memory cells are in the first semiconductor layer in a plan view.

In general, according to some aspects, a semiconductor memory device includes a first semiconductor layer and a second semiconductor layer. The first semiconductor layer includes a memory cell array connected to a plurality of word-lines and a plurality of bit-lines. The memory cell array includes a plurality of memory cells to store data, the plurality of word-lines extend in a first direction and the plurality of bit-lines extend in a second direction crossing the first direction. The second semiconductor layer is under the first semiconductor layer in a third direction perpendicular to both the first direction and the second direction and includes a peripheral circuit to control the memory cell array. The peripheral circuit includes one or more sub word-line drivers and a sub word-line decoder. The one or more sub word-line drivers drive the plurality of word-lines. The sub word-line decoder applies a word-line enable signal to the one or more sub word-line drivers based on a first intermediate word-line enable signal and a second intermediate word-line enable signal. A first region in which the one or more sub word-line drivers and the sub word-line decoder are in the second semiconductor layer is under a memory region in which the plurality of memory cells are in the first semiconductor layer in a plan view. The sub word-line decoder generates the word-line enable signal based on the first intermediate word-line enable signal and the second intermediate word-line enable signal. Each of the first intermediate word-line enable signal and the second intermediate word-line enable signal swings between a power supply voltage and a ground voltage. The word-line enable signal swings between the power supply voltage and a negative voltage.

In general, according to some aspects, the semiconductor memory device and the memory package may have or adopt a structure in which the peripheral circuit and the memory cell array are stacked, e.g., the COP structure in which the peripheral circuit is formed below and then the memory cell array is stacked on the peripheral circuit. Accordingly, the memory device and the memory package may have a relatively small size.

In addition, the semiconductor memory device and the memory package may reduce wirings by arranging a sub word-line decoder adjacent to sub word-line drivers under a memory cell array and may reduce NBTI occurring in the PMOS transistors in the sub word-line drivers and PBTI occurring in the NMOS transistors in the sub word-line drivers because the sub word-line decoder applies the word-line enable signal swinging between the power supply voltage and the negative voltage to the sub word-line drivers.

### BRIEF DESCRIPTION OF THE DRAWINGS

Illustrative, non-limiting example implementations will be more clearly understood from the following detailed description taken in conjunction with the accompanying drawings.

FIG. 1 is a perspective view of an example of a semiconductor memory device.

FIG. 2A is a cross-sectional view of an example of a semiconductor memory device.

FIG. 2B is a cross-sectional view of an example of a semiconductor memory device.

FIGS. 3A and 3B illustrate examples of a first region in FIG. 2A or in FIG. 2B.

FIG. 4 is a diagram schematically illustrating an example of a structure of a memory cell region and a peripheral circuit region of a semiconductor memory device.

FIG. 5 is a block diagram illustrating an example of a semiconductor memory device.

FIG. 6 illustrates an example of the first bank array in the semiconductor memory device of FIG. 5.

FIG. 7 is a block diagram illustrating an example of the first row decoder in the semiconductor memory device of FIG. 5.

FIG. 8 is a circuit diagram illustrating an example main word-line driver of the plurality of main word-line drivers in FIG. 7.

FIG. 9 illustrates an example of a sub word-line decoder and one or more example sub word-line drivers.

FIG. 10 is a circuit diagram illustrating an example of the sub word-line decoder in FIG. 9.

FIG. 11 is a circuit diagram illustrating an example sub word-line driver of the sub word-line drivers in FIG. 9.

FIG. 12A is a waveform diagram illustrating an example of an operation of the sub word-line decoder of FIG. 10.

FIG. 12B is a waveform diagram illustrating an example of an operation of the sub word-line driver of FIG. 11.

FIG. 13 is a diagram for describing an example of a semiconductor memory device of FIG. 2A.

FIG. 14 is a circuit diagram illustrating an example of the bit-line sense amplifier in FIG. 3A or in FIG. 3B.

FIGS. 15 and 16 are perspective views of an example of a semiconductor memory device.

FIGS. 17 and 18 are cross-sectional views of an example of a memory package.

FIG. 19 is a block diagram illustrating an example of a memory system.

FIG. 20 is a block diagram illustrating an example of the memory controller in FIG. 19.

FIG. 21 is a flow chart illustrating an example of a method of manufacturing a semiconductor memory device.

FIG. 22 is a diagram illustrating an example of a manufacturing process of a semiconductor device.

### DETAILED DESCRIPTION

Various example implementations will be described more fully with reference to the accompanying drawings, in which implementations are shown. The present disclosure may, however, be implemented in many different forms and should not be construed as limited to the implementations set forth herein. Like reference numerals refer to like elements throughout this application.

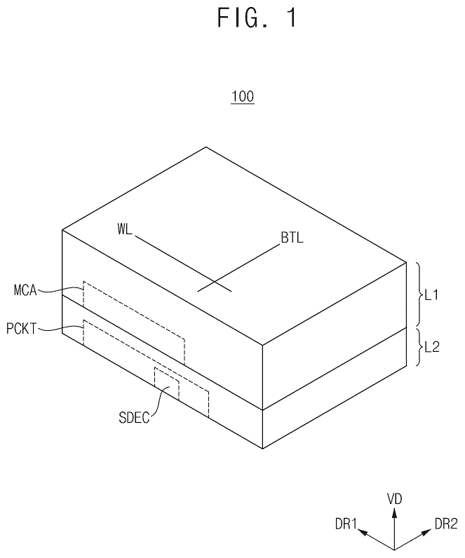

FIG. 1 is a perspective view of an example of a semiconductor memory device.

In FIG. 1, two directions that are each parallel or substantially parallel to a first surface (e.g., a top surface) of a substrate and crossing each other are referred to as a first direction DR1 (e.g., an X-axis direction) and a second direction DR2 (e.g., a Y-axis direction). In addition, a direction vertical or substantially vertical to the first surface of the substrate is referred to as a third direction VD (e.g., a Z-axis direction). The third direction VD may be referred to as a vertical direction. For example, the first and second directions DR1 and DR2 may be perpendicular or substantially perpendicular to each other. In addition, the third direction VD may be perpendicular or substantially perpendicular to both the first and second directions DR1 and DR2. Further, a direction indicated by an arrow in the figures and a reverse direction thereof are considered as the same direction. The definition of the first, second and third directions DR1, DR2 and VD are same in the subsequent figures.

Referring to FIG. 1, a semiconductor memory device 100 may include a first semiconductor layer L1 and a second semiconductor layer L2.

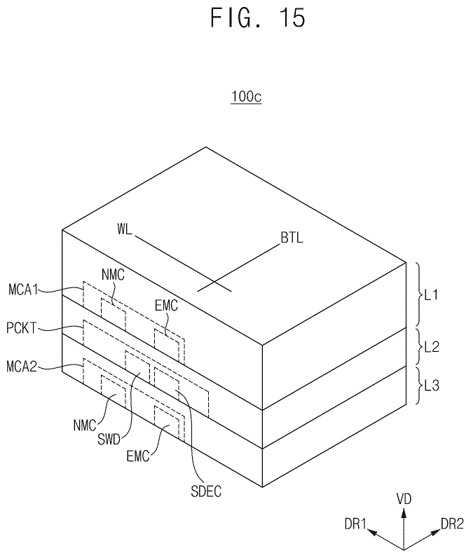

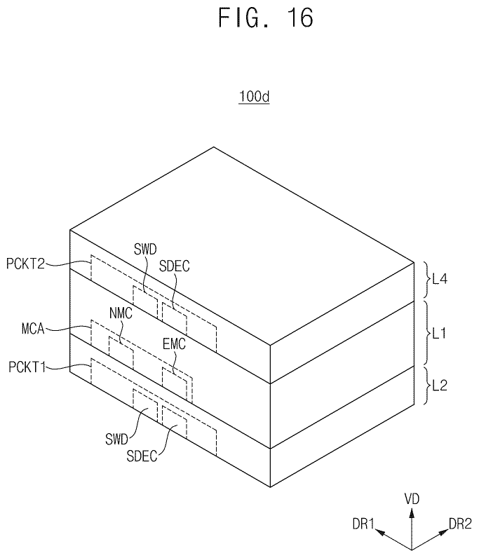

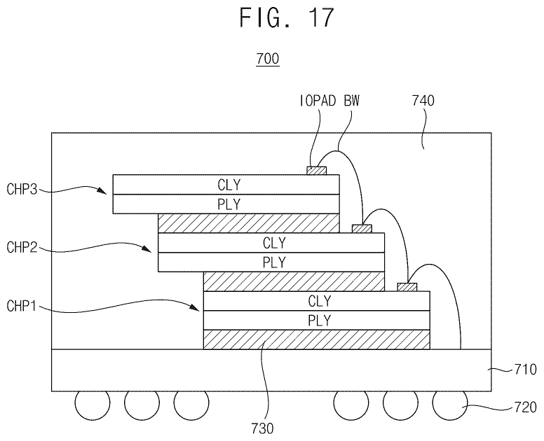

The first semiconductor layer L1 and the second semiconductor layer L2 may be disposed or stacked in the third direction VD. For example, the first semiconductor layer L1 may be stacked on the second semiconductor layer L2 in the third direction VD, and the second semiconductor layer L2 may be disposed under (e.g., directly beneath or indirectly beneath) the first semiconductor layer L1 in the third direction VD. However, example implementations are not limited thereto. For example, the semiconductor memory device 100 may be turned over during the manufacturing process, and thus the second semiconductor layer L2 may be stacked on the first semiconductor layer L1 in the third direction VD. In some implementations, as will be described with reference to FIGS. 15 and 16, three or more semiconductor layers may be stacked in the third direction VD.

The first semiconductor layer L1 may include a plurality of word-lines WL, a plurality of bit-lines BTL and a memory cell array MCA. Thus, the first semiconductor layer L1 may be referred to as a memory cell region or a cell wafer.

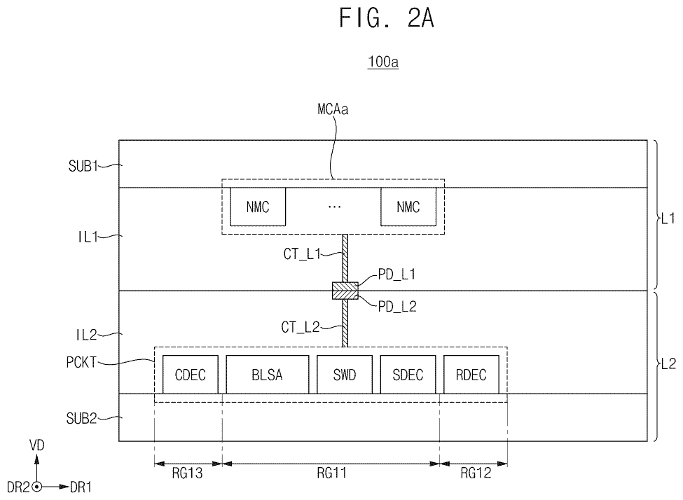

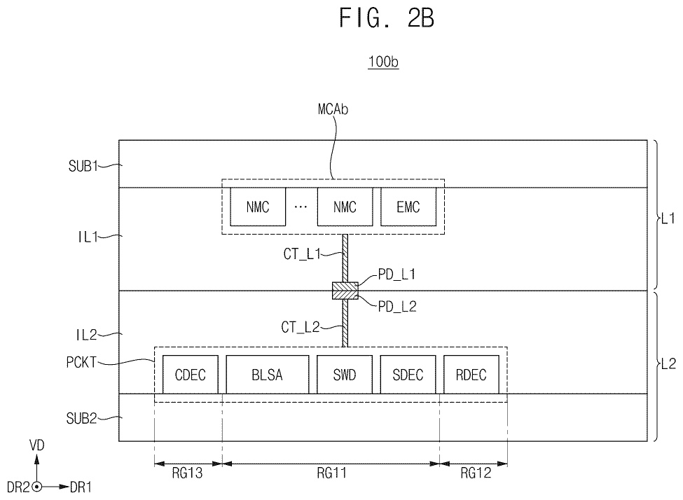

For example, as will be described with reference to FIGS. 2A and 2B, the first semiconductor layer L1 may include a first substrate. The plurality of word-lines WL, the plurality of bit-lines BTL and the memory cell array MCA may be disposed and/or formed on the first substrate. For example, each of the plurality of word-lines WL may extend in the first direction DR1, and the plurality of word-lines WL may be arranged along the second direction DR2. For example, each of the plurality of bit-lines BTL may extend in the second direction DR2, and the plurality of bit-lines BTL may be arranged along the first direction DR1. For example, the memory cell array MCA may be connected to the plurality of word-lines WL and the plurality of bit-lines BTL.

The second semiconductor layer L2 may include a peripheral circuit PCKT that controls the memory cell array MCA. Thus, the second semiconductor layer L2 may be referred to as a peripheral circuit region or a peripheral wafer.

For example, as will be described with reference to FIGS. 2A and 2B, the second semiconductor layer L2 may include a second substrate. The peripheral circuit PCKT may be disposed and/or formed on the second substrate. For example, the peripheral circuit PCKT may control the memory cell array MCA.

In some implementations, the first semiconductor layer L1 and the second semiconductor layer L2 may be manufactured separately, and then the first semiconductor layer L1 and the second semiconductor layer L2 may be connected to each other by a bonding scheme (or method). For example, as will be described with reference to FIGS. 2A and 2B, the first semiconductor layer L1 may include a first bonding pad, the second semiconductor layer L2 may include a second bonding pad, and the bonding scheme may represent a method of electrically or physically connecting a bonding metal pattern (e.g., the first bonding pad) formed in the first semiconductor layer L1 to a bonding metal pattern (e.g., the second bonding pad) formed in the second semiconductor layer L2. For example, the bonding pads may be formed of copper (Cu), and the bonding scheme may be a Cu—Cu bonding scheme. Alternatively, the bonding pads may be formed of aluminum (Al) or tungsten (W).

The memory cell array MCA may include a plurality of normal memory cells. The peripheral circuit PCKT may include a sub word-line decoder SDEC. The sub word-line decoder SDEC may provide one or more sun word-line drivers with a word-line enable signal that swings between a power supply voltage and a negative voltage. The plurality of memory cells in the first semiconductor layer L1 and the sub word-line decoder SDEC in the second semiconductor layer L2 may be arranged to partially and/or completely overlap in a plan view or on a plane, which will be described with reference to FIGS. 2A and 2B. That is, a first region in which the sub word-line decoder SDEC is in the second semiconductor layer L2 may be under a memory region in which the memory cell array MCA in the first semiconductor layer L1. For example, the memory region may overlap the first region.

FIG. 2A is a cross-sectional view of an example of a semiconductor memory device.

Referring to FIGS. 1 and 2A, a semiconductor memory device 100a may include the first semiconductor layer L1 and the second semiconductor layer L2.

The first semiconductor layer L1 may include a first substrate SUB1, a memory cell array MCAa, a first bonding pad PD_L1, a first contact CT_L1 and a first insulating layer IL1. The second semiconductor layer L2 may include a second substrate SUB2, the peripheral circuit PCKT, a second bonding pad PD_L2, a second contact CT_L2 and a second insulating layer IL2.

The first substrate SUB1 may be a supporting layer that supports components (or elements) of the first semiconductor layer L1, and the second substrate SUB2 may be a supporting layer that supports components of the second semiconductor layer L2. For example, each of the first and second substrates SUB1 and SUB2 may be a silicon substrate, and may be referred to as a base substrate. The first insulating layer IL1 may cover the components of the first semiconductor layer L1, and the second insulating layer IL2 may cover the components of the second semiconductor layer L2.

The memory cell array MCAa may include a plurality of normal memory cells NMC. The peripheral circuit PCKT may include a row decoder RDEC, bit-line sense amplifiers BLSA, sub-word-line drivers SWD, a sub word-line decoder SDEC and a column decoder CDEC, etc.

The bit-line sense amplifiers BLSA, the sub-word-line drivers SWD and the sub word-line decoder SDEC may be disposed in a first region RG11 in the second semiconductor layer L2, the row decoder RDEC may be disposed in a second region RG12 adjacent to the first region RG11 in the second semiconductor layer L2 and the column decoder CDEC may be disposed in a third region RG13 adjacent to the first region RG11 in the second semiconductor layer L2. The first region RG11 in which the bit-line sense amplifiers BLSA, the sub-word-line drivers SWD and the sub word-line decoder SDEC are disposed may be under a memory region in which the memory cell array MCAa is disposed in the first semiconductor layer L1 in the vertical direction VD. That is, the first region RG11 may be under the memory cell array MCAa (e.g., the memory region) in a plan view.

The memory cell array MCAa and the peripheral circuit PCKT may be electrically connected to each other by the first and second contacts CT_L1 and CT_L2 and the first and second bonding pads PD_L1 and PD_L2. For example, the memory cell array MCAa may be electrically connected to the first contact CT_L1 and the first bonding pad PD_L1, the peripheral circuit PCKT may be electrically connected to the second contact CT_L2 and the second bonding pad PD_L2, and the memory cell array MCAa and the peripheral circuit PCKT may be electrically connected to each other by electrically connecting the first bonding pad PD_L1 with the second bonding pad PD_L2. Although not illustrated in detail, at least one conductive line and/or contact may be further formed to connect the memory cell array MCAa with the first bonding pad PD_L1, and at least one conductive line and/or contact may be further formed to connect the peripheral circuit PCKT with the second bonding pad PD_L2.

In some implementations, the first semiconductor layer L1 may be manufactured by forming the memory cell array MCAa, the first bonding pad PD_L1, the first contact CT_L1 and the first insulating layer IL1 in and/or on the first substrate SUB1, the second semiconductor layer L2 may be manufactured by forming the peripheral circuit PCKT, the second bonding pad PD_L2, the second contact CT_L2 and the second insulating layer IL2 in and/or on the second substrate SUB2, the first semiconductor layer L1 may be turned over, and the bonding pads PD_L1 and PD_L2 may be connected using the bonding scheme. As a result, the first and second semiconductor layers L1 and L2 may be electrically connected in the third direction VD.

Although FIG. 2A illustrates an example where the semiconductor layers L1 and L2 include a pair of the bonding pads PD_L1 and PD_L2 and a pair of the contacts CT_L1 and CT_L2, example implementations are not limited thereto, and the number of bonding pads and the number of contacts included in the semiconductor layers L1 and L2 may be variously determined.

The semiconductor memory device 100a may have or adopt a structure in which the peripheral circuit PCKT and the memory cell array MCAa are stacked, e.g., a cell over periphery (COP) structure in which the peripheral circuit PCKT is formed below and then the memory cell array MCAa is stacked on the peripheral circuit PCKT. Accordingly, the semiconductor memory device 100a may have a relatively small size.

FIG. 2B is a cross-sectional view of an example of a semiconductor memory device.

In FIG. 2B, the descriptions repeated with or overlapping with descriptions of FIG. 2A will be omitted in the interest of brevity.

Referring to FIGS. 1 and 2B, a semiconductor memory device 100b may include the first semiconductor layer L1 and the second semiconductor layer L2.

The first semiconductor layer L1 may include a first substrate SUB1, a memory cell array MCAb, a first bonding pad PD_L1, a first contact CT_L1 and a first insulating layer IL1. The second semiconductor layer L2 may include a second substrate SUB2, the peripheral circuit PCKT, a second bonding pad PD_L2, a second contact CT_L2 and a second insulating layer IL2.

The memory cell array MCAb may include a plurality of normal memory cells NMC and a plurality of error correction code (ECC) memory cells EMC. The plurality of normal memory cells NMC may store normal data (e.g., user data), and the plurality of ECC memory cells EMC may store ECC data (e.g., parity data) that is associated with or related to the normal data.

In computing, telecommunication, information theory, and coding theory, forward error correction (FEC) or channel coding is a technique used for controlling errors in data transmission over unreliable or noisy communication channels. For example, the sender encodes the message in a redundant way, most often by using an error correction code or ECC. The redundancy allows the receiver not only to detect errors that may occur anywhere in the message, but often to correct a limited number of errors. Therefore, a reverse channel to request re-transmission may not be needed.

For example, when the normal data is written into the plurality of normal memory cells NMC, the ECC data associated with the normal data to be written may be generated using an ECC encoder and an ECC. The normal data and the ECC data may be stored in the plurality of normal memory cells NMC and the plurality of ECC memory cells EMC, respectively. For example, when the normal data is read from the plurality of normal memory cells NMC, an ECC decoding may be performed on the normal data based on the ECC data using an ECC decoder and an ECC. When it is determined based on a result of the ECC decoding that the normal data includes at least one error bit, the ECC decoder may perform an error correction and output corrected normal data in a case of a correctable error (CE), and the ECC decoder may declare that the ECC decoding is impossible in a case of an uncorrectable error (UE). For example, the ECC may be a single error correction (SEC) code or a single error correction and double error detection (SECDED) code, but example implementations are not limited thereto.

The bit-line sense amplifiers BLSA, the sub-word-line drivers SWD and the sub word-line decoder SDEC may be disposed in a first region RG11 in the second semiconductor layer L2, the row decoder RDEC may be disposed in a second region RG12 adjacent to the first region RG11 in the second semiconductor layer L2 and the column decoder CDEC may be disposed in a third region RG13 adjacent to the first region RG11 in the second semiconductor layer L2. The first region RG11 in which the bit-line sense amplifiers BLSA, the sub-word-line drivers SWD and the sub word-line decoder SDEC are disposed may be under a memory region in which the memory cell array MCAb is disposed in the first semiconductor layer L1 in the vertical direction VD. That is, the first region RG11 may be under the memory cell array MCAa (e.g., the memory region) in a plan view.

The memory cell array MCAb and the peripheral circuit PCKT may be electrically connected to each other by the first and second contacts CT_L1 and CT_L2 and the first and second bonding pads PD_L1 and PD_L2.

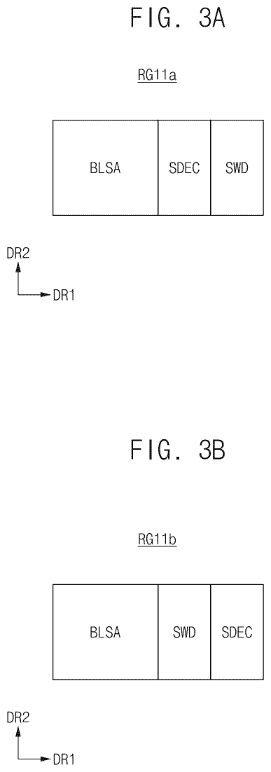

FIGS. 3A and 3B illustrate examples of a first region in FIG. 2A or in FIG. 2B.

Referring to FIG. 3A, the bit-line sense amplifier BLSA, the sub word-line decoder SDEC and the one or more sub word-line drivers SWD may be disposed in a first region RG11a and may be arranged in the first direction DR1. The one or more sub word-line drivers SWD may be disposed adjacent to a first side, which extends in the second direction DR2, of the sub word-line decoder SDEC.

Referring to FIG. 3B, the bit-line sense amplifier BLSA, the one or more sub word-line drivers SWD and the sub word-line decoder SDEC may be disposed in a first region RG11b and may be arranged in the first direction DR1. The one or more sub word-line drivers SWD may be disposed adjacent to a second side, which extends in the second direction DR2, of the sub word-line decoder SDEC. The second side may be opposite to a first side of the sub word-line decoder SDEC. That is, the one or more sub word-line drivers SWD may be disposed between the bit-line sense amplifier BLSA and the sub word-line decoder SDEC.

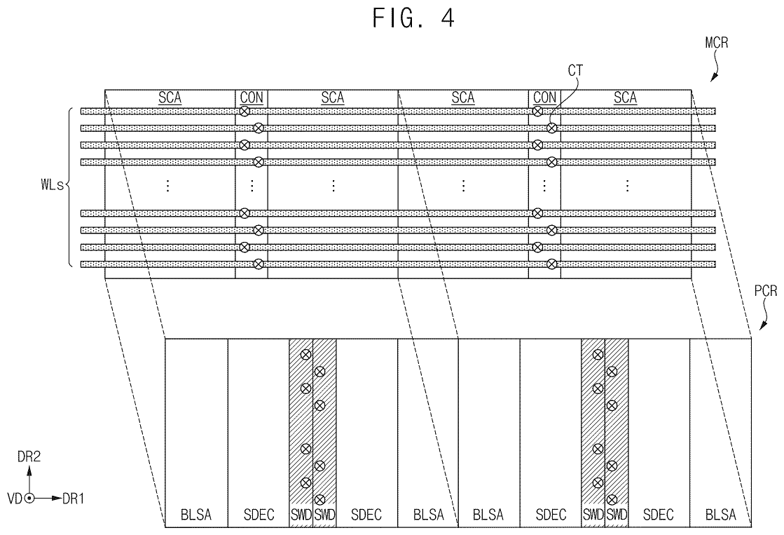

FIG. 4 is a diagram schematically illustrating an example of a structure of a memory cell region and a peripheral circuit region of a semiconductor memory device.

Referring to FIG. 4, a memory cell region MCR may include a plurality of sub-array regions SCA and a plurality of contact regions CON. A plurality of memory cells may be formed in each of the sub-array regions SCA. In this case, the memory cell may include a cell transistor and a cell capacitor, and each of the memory cells formed in the sub-array regions SCA may include a cell transistor connected to a bit-line and a word-line, and a cell capacitor. The memory cell region MCR in FIG. 4 may correspond to the memory cell array MCA in FIG. 1.

The memory cell array MCA in FIG. 1 may include a plurality of memory blocks. Memory cells connected to the word-lines WL may constitute a single memory block. Each of the sub-array regions SCA may be included in the single memory block and may be a unit array region. At least one surface of each of the sub-array regions SCA may be disposed to be apart from other sub-array regions SCA.

Each of the contact regions CON may be located between two different sub-array regions SCA. A plurality of contacts CT may be located in each of the contact regions CON. The contacts CT may electrically connect the word-lines WL to the sub word-line drivers formed in the peripheral circuit region PCR.

A plurality of word-lines WLs extending in the first direction DR1 may be located in the memory cell region MCR. For example, the word-lines WLs may extend in the first direction DR1 and may be spaced apart from each other in the second direction DR2 to be parallel to each other.

In some implementations, the word-lines WLs may extend to cross the sub-array regions SCA and the contact regions CON.

A plurality of contacts CT connected to all of the word-lines WLs crossing the contact regions CON may be formed in each of the contact regions CON. That is, all of the word-lines WLs located in two sub-array regions SCA disposed to be adjacent to the contact region CON may be driven through the contacts CT formed in one contact region CON.

The peripheral circuit region PCR may include a plurality of sub word-line driver areas SWD, a plurality of sub word-line decoders SDEC and a plurality of bit-line sense amplifiers BLSA. For example, the sub word-line driver SWD, the sub word-line decoder SDEC and the bit-line sense amplifier BLSA corresponding to one sub-array region SCA may be sequentially arranged in the first direction DR1 on a plane extending in the first direction DR1 and the second direction DR2.

In some implementations, each of the sub word-line drivers SWD may be located (e.g., disposed) below corresponding one of the contact regions CON (e.g., in the vertical direction VD) and may be electrically connected to the contacts CT.

The sub-word line decoder SDEC may generate a word-line enable signal which swings between a power supply voltage and a negative voltage by decoding a first intermediate word-line enable signal and a second intermediate word-line enable signal, each of which swings between the power supply voltage and a ground voltage and may provide the word-line enable signal to adjacent sub word-line drivers SWD.

The bit-line sense amplifiers BLSA may be connected to bit-lines formed in the sub-array regions SCA, and may be configured to read data from or write data to memory cells formed in the sub-array regions SCA.

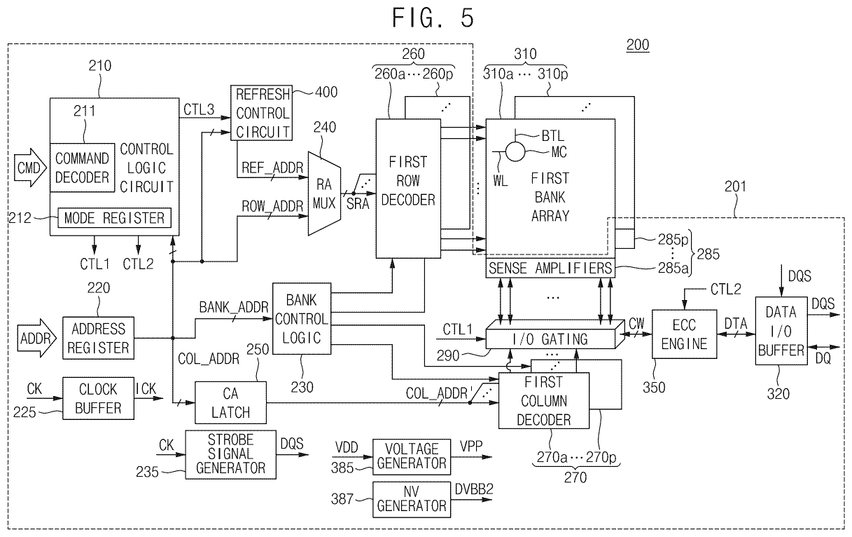

FIG. 5 is a block diagram illustrating an example of a semiconductor memory device.

Referring to FIG. 5, a semiconductor memory device 200 may include a peripheral circuit 201 and a memory cell array 310.

The peripheral circuit 201 may include a control logic circuit 210, an address register 220, a bank control logic 230, a refresh control circuit 400, a row address multiplexer 240, a column address latch 250, a row decoder 260, a column decoder 270, a sense amplifier unit 285, an input/output (I/O) gating circuit 290, an error correction code (ECC) engine 350, a clock buffer 225, a strobe signal generator 235, a voltage generator 385, a negative voltage (NV) generator 387 and a data I/O buffer 320.

The memory cell array 310 may include first through sixteenth bank arrays 310a˜310p. The row decoder 260 may include first through sixteenth row decoders 260a˜260p respectively coupled to the first through sixteenth bank arrays 310a˜310p, the column decoder 270 may include first through sixteenth column decoders 270a˜270p respectively coupled to the first through sixteenth bank arrays 310a˜310p, and the sense amplifier unit 285 may include first through sixteenth sense amplifiers 285a˜285p respectively coupled to the first through sixteenth bank arrays 310a˜310p.

The first through sixteenth bank arrays 310a˜310p, the first through sixteenth row decoders 260a˜260p, the first through sixteenth column decoders 270a˜270p and first through sixteenth sense amplifiers 285a˜285p may form first through sixteenth banks. Each of the first through sixteenth bank arrays 310a˜310p includes a plurality of memory cells MC formed at intersections of a plurality of word-lines WL and a plurality of bit-line BTL.

The address register 220 may receive the address ADDR including a bank address BANK_ADDR, a row address ROW_ADDR and a column address COL_ADDR from an external memory controller. The address register 220 may provide the received bank address BANK_ADDR to the bank control logic 230, may provide the received row address ROW_ADDR to the row address multiplexer 240 and the refresh control circuit 400, and may provide the received column address COL_ADDR to the column address latch 250.

The bank control logic 230 may generate bank control signals in response to the bank address BANK_ADDR. One of the first through sixteenth row decoders 260a˜260p corresponding to the bank address BANK_ADDR is activated in response to the bank control signals, and one of the first through sixteenth column decoders 270a˜270p corresponding to the bank address BANK_ADDR is activated in response to the bank control signals.

The row address multiplexer 240 may receive the row address ROW_ADDR from the address register 220, and may receive a refresh row address REF_ADDR from the refresh control circuit 400. The row address multiplexer 240 may selectively output the row address ROW_ADDR or the refresh row address REF_ADDR as a row address SRA. The row address SRA that is output from the row address multiplexer 240 is applied to the first through sixteenth row decoders 260a˜260p.

The refresh control circuit 400 may sequentially increase or decrease the refresh row address REF_ADDR in response to a third control signal CTL3 from the control logic circuit 210.

The activated one of the first through sixteenth row decoders 260a˜260p, by the bank control logic 230, may decode the row address SRA that is output from the row address multiplexer 240, and may activate a word-line corresponding to the row address SRA. For example, the activated bank row decoder applies a word-line driving voltage to the word-line corresponding to the row address.

The column address latch 250 may receive the column address COL_ADDR from the address register 220, and may temporarily store the received column address COL_ADDR. In some implementations, in a burst mode, the column address latch 250 may generate column address COL_ADDR′ that increments from the received column address COL_ADDR. The column address latch 250 may apply the temporarily stored or generated column address COL_ADDR′ to the first through sixteenth column decoders 270a˜270p.

The activated one of the first through sixteenth column decoders 270a˜270p may activate a sense amplifier corresponding to the bank address BANK_ADDR and the column address COL_ADDR through the I/O gating circuit 290.

The I/O gating circuit 290 may include a circuitry for gating input/output data, and may further include input data mask logic, read data latches for storing data that is output from the first through sixteenth bank arrays 310a˜310p, and write drivers for writing data to the first through sixteenth bank arrays 310a˜310p.

Codeword CW read from a selected one bank array of the first through sixteenth bank arrays 310a˜310p may be sensed by a sense amplifier coupled to the selected one bank array from which the data is to be read, and may be stored in the read data latches. The codeword CW stored in the read data latches may be provided to the data I/O buffer 320 as data DTA after ECC decoding is performed on the codeword CW by the ECC engine 350. The data I/O buffer 320 may convert the data DTA into the data signal DQ and may transmit the data signal DQ along with the data strobe signal DQS to the external memory controller.

The data signal DQ to be written in a selected one bank array of the first through sixteenth bank arrays 310a˜310p may be provided to the data I/O buffer 320 from the external memory controller. The data I/O buffer 320 may convert the data signal DQ to the data DTA and may provide the data DTA to the ECC engine 350. The ECC engine 350 may perform an ECC encoding on the data DTA to generate parity bits, and the ECC engine 350 may provide the codeword CW including data DTA and the parity bits to the I/O gating circuit 290. The I/O gating circuit 290 may write the codeword CW in a sub-page in the selected one bank array through the write drivers.

The data I/O buffer 320 may provide the data signal DQ from the external memory controller to the ECC engine 350 by converting the data signal DQ to the data DTA in a write operation of the semiconductor memory device 200 and may convert the data DTA to the data signal DQ from the ECC engine 350 and may transmit the data signal DQ and the data strobe signal DQS to the external memory controller in a read operation of the semiconductor memory device 200.

The ECC engine 350 may perform an ECC encoding on the data DTA and may perform an ECC decoding on the codeword CW based on a second control signal CTL2 from the control logic circuit 210.

The clock buffer 225 may receive the clock signal CK, may generate an internal clock signal ICK by buffering the clock signal CK, and may provide the internal clock signal ICK to circuit components processing the command CMD and the address ADDR.

The strobe signal generator 235 may receive the clock signal CK, may generate the data strobe signal DQS based on the clock signal CK and may provide the data strobe signal DQS to the data I/O buffer 320.

The voltage generator 385 may generate a power supply voltage VPP based on an external voltage VDD received from an outside device and may provide the power supply voltage VPP to the sub word-line decoder, the sub word-line drivers, etc.

The negative voltage generator 387 may generate a negative voltage DVBB2 and may provide the negative voltage DVBB2 to the sub word-line decoder, the sub word-line drivers, etc.

Although not illustrated, the sub word-line decoder and the sub word-line drivers may be disposed under the memory cell array 310.

The control logic circuit 210 may control operations of the semiconductor memory device 200. For example, the control logic circuit 210 may generate control signals for the semiconductor memory device 200 in order to perform a write operation, a read operation and a refresh operation. The control logic circuit 210 includes a command decoder 211 that decodes the command CMD received from the external memory controller and a mode register 212 that sets an operation mode of the semiconductor memory device 200.

For example, the command decoder 211 may generate the control signals corresponding to the command CMD by decoding a write enable signal, a row address strobe signal, a column address strobe signal, a chip select signal, etc. The control logic circuit 210 may generate a first control signal CTL1 to control the I/O gating circuit 290, the second control signal CTL2 to control the ECC engine 350 and the third control signal CTL3 to control the refresh control circuit 400.

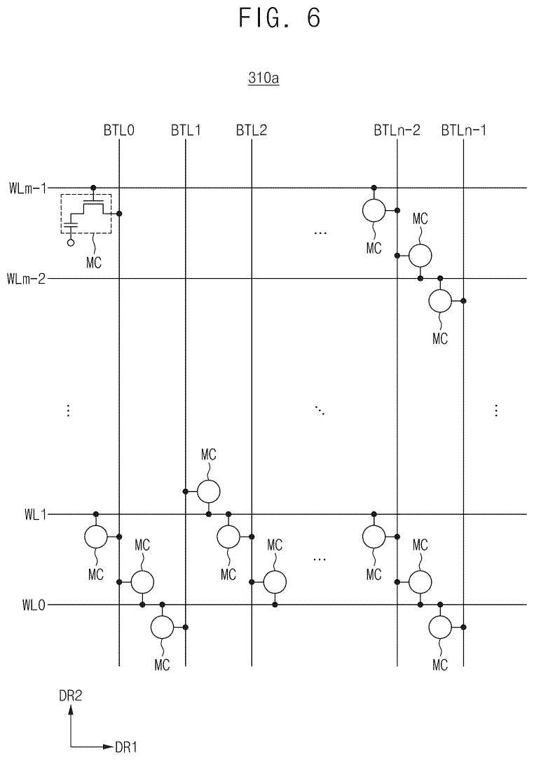

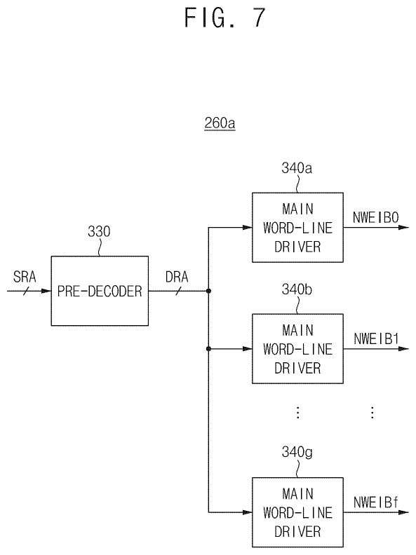

FIG. 6 illustrates an example of the first bank array in the semiconductor memory device of FIG. 5.

Referring to FIG. 6, the first bank array 310a may include a plurality of word-lines WL0˜WLm-1 (m is a natural number greater than two), a plurality of bit-lines BL0˜BLn-1 (n is a natural number greater than two), and a plurality of memory cells MCs disposed at intersections between the word-lines WL0˜WLm-1 and the bit-lines BL0˜BLn-1. Each of the memory cells MCs includes a cell transistor coupled to each of the word-lines WL0˜WLm-1 and each of the bit-lines BL0˜BLn-1 and a cell capacitor coupled to the cell transistor.

Each of the memory cells MCs may have a DRAM cell structure. Each of the word-lines WL0˜WLm-1 extends in the first direction DR1 and each of the bit-lines BL1˜BLn-1 extends in the second direction DR2 crossing the first direction DR1.

The word-lines WL0˜WLm-1 coupled to the plurality of memory cells MCs may be referred to as rows of the first bank array 310a and the bit-lines BL0˜BLn-1 coupled to the plurality of memory cells MCs may be referred to as columns of the first bank array 310a.

Although the semiconductor memory device is described based on a DRAM, the semiconductor memory device may be any volatile memory device, and/or any nonvolatile memory device, e.g., a static random access memory (SRAM), a flash memory, a phase-change random access memory (PRAM), a resistive random access memory (RRAM), a magnetic random access memory (MRAM), a ferroelectric random access memory (FRAM), or the like.

FIG. 7 is a block diagram illustrating an example of the first row decoder in the semiconductor memory device of FIG. 5.

Referring to FIG. 7, the first row decoder 260a may include a pre-decoder 330 and a plurality of main word-line drivers 340a, 340b, . . . , 340g. Here, g may be an integer greater than two.

The pre-decoder 330 may generate a decoded row address DRA by decoding the row address SRA and may provide the decoded row address DRA to the plurality of main word-line drivers 340a, 340b, . . . , 340g.

Each of the plurality of main word-line drivers 340a, 340b, . . . , 340g may generate a respective one of intermediate word-line enable signals NWEIB0, NWEIB1, . . . , NWEIBf based on the decoded row address DRA and may provide at least a portion of the intermediate word-line enable signals NWEIB0, NWEIB1, . . . , NWEIBf to a corresponding sub word-line decoder. Here, g may be an integer greater than one.

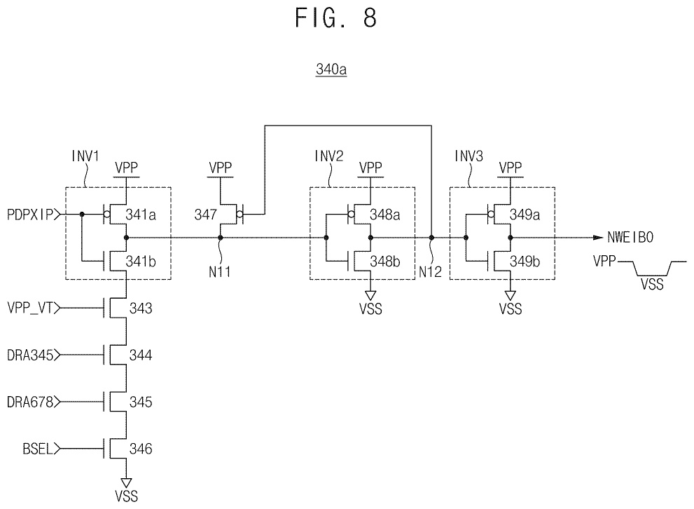

FIG. 8 is a circuit diagram illustrating an example main word-line driver of the plurality of main word-line drivers in FIG. 7.

Although, a configuration of the main word-line driver 340a is illustrated for convenience of explanation in FIG. 8, each configuration of the main word-line drivers 340b, . . . , 340g may be substantially the same as the configuration of the main word-line driver 340 a.

Referring to FIG. 8, the main word-line driver 340a may include inverters INV1, INV2 and INV3, n-channel metal-oxide semiconductor (NMOS) transistors 343, 344, 345 and 346 and a keeper transistor 347.

The inverter INV1 may include a p-channel metal-oxide semiconductor (PMOS) transistor 341a and an NMOS transistor 341b. The PMOS transistor 341a may be connected between a power supply voltage VPP and a first node N11 and may have a gate to receive a block access signal PDPXIP. The NMOS transistor 341b may be connected between the first node N11 and the NMOS transistor 343 and may have a gate to receive the block access signal PDPXIP. The NMOS transistors 343, 344, 345 and 346 may be connected in series between the NMOS transistor 341b and a ground voltage VSS.

The NMOS transistor 343 may have a gate to receive a control signal VPP_VT, the NMOS transistor 344 may have a gate to receive a decoded row address DRA345, the NMOS transistor 345 may have a gate to receive a decoded row address DRA678 and the NMOS transistor 346 may have a gate to receive a block selection signal BSEL.

Each of the NMOS transistors 341b, 343, 344, 345 and 346 may constitute a pull-down network to discharge the first node N11 with the ground voltage VSS when each of the NMOS transistors 341b, 343, 344, 345 and 346 is turned-on based on respective one of the block access signal PDPXIP, the control signal VPP_VT, the decoded row address DRA345, the decoded row address DRA678 and the block selection signal BSEL.

The inverter INV2 may include a PMOS transistor 348a and an NMOS transistor 348b. The PMOS transistor 348a may be connected between the power supply voltage VPP and a second node N12 and may have a gate coupled to the first node N11. The NMOS transistor 348b may be connected between the second node N12 and the ground volage VSS and may have a gate coupled to the first node N11. Therefore, the inverter INV2 may invert a logic level of the first node N11 and may output the inverted logic level to the second node N12.

The inverter INV3 may include a PMOS transistor 349a and an NMOS transistor 349b. The PMOS transistor 349a may be connected between the power supply voltage VPP and a third node N13 and may have a gate coupled to the second node N12. The NMOS transistor 349b may be connected between the third node N13 and the ground volage VSS and may have a gate coupled to the second node N12. Therefore, the inverter INV3 may invert a logic level of the second node N12 and may output a first intermediate word-line enable signal NWEIB0 swinging between the power supply voltage VPP and the ground voltage VSS at the third node N13.

The keeper transistor 347 may be connected between the power supply voltage VPP and the first node N11 and may have a gate coupled to the second node N12. Therefore, the keeper transistor 347 may maintain a logic level of the first node N11 with a logic high level based on a logic level of the second node N12.

Each of the main word-line drivers 340b, . . . , 340g may generate a respective one of the intermediate word-line enable signals NWEIB1, . . . , NWEIBf, each of which swings between the power supply voltage VPP and the ground voltage VSS.

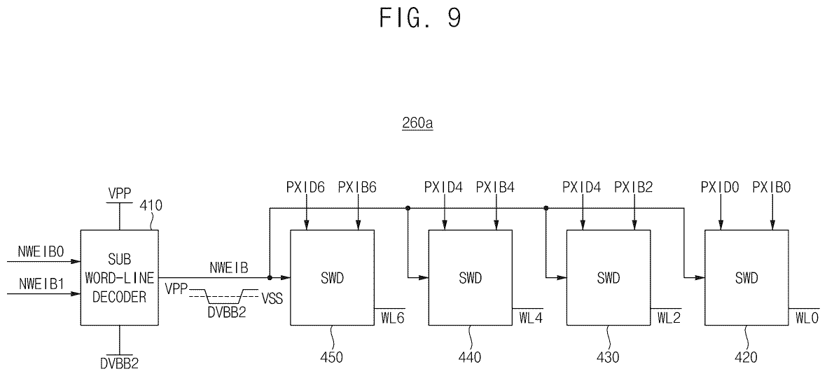

FIG. 9 illustrates an example of a sub word-line decoder and one or more example sub word-line drivers.

Referring to FIG. 9, a sub word-line decoder 410 may apply a word-line enable signal NWEIB to one or more sub word-line drivers 420, 430, 440 and 450.

The sub word-line decoder 410 may correspond to the sub word-line decoder SDEC in FIG. 2A or FIG. 2B and the one or more sub word-line drivers 420, 430, 440 and 450 may correspond to the sub word-line drivers SWD in FIG. 2A or FIG. 2B.

The sub word-line decoder 410 may be coupled to the power supply voltage VPP and the negative voltage DVBB2, may receive the first intermediate word-line enable signal NWEIB0 and the second intermediate word-line enable signal NWEIB1, may generate the word-line enable signal NWEIB swinging between the power supply voltage VPP and the negative voltage DVBB2 by decoding the first intermediate word-line enable signal NWEIB0 and the second intermediate word-line enable signal NWEIB1 and may apply (e.g., provide) the word-line enable signal NWEIB to the sub word-line drivers 420, 430, 440 and 450.

Each of the first intermediate word-line enable signal NWEIB0 and the second intermediate word-line enable signal NWEIB1 may swing between the power supply voltage VPP and the ground voltage VSS.

The sub word-line driver 420 may drive a corresponding word-line WL0 with the power supply voltage VPP or the negative voltage DVBB2 based on the word-line enable signal NWEIB, a first driving signal PXID0 and a second driving signal PXIB0. The sub word-line driver 430 may drive a corresponding word-line WL2 with the power supply voltage VPP or the negative voltage DVBB2 based on the word-line enable signal NWEIB, a first driving signal PXID2 and a second driving signal PXIB2.

The sub word-line driver 440 may drive a corresponding word-line WL4 with the power supply voltage VPP or the negative voltage DVBB2 based on the word-line enable signal NWEIB, a first driving signal PXID4 and a second driving signal PXIB4. The sub word-line driver 450 may drive a corresponding word-line WL6 with the power supply voltage VPP or the negative voltage DVBB2 based on the word-line enable signal NWEIB, a first driving signal PXID6 and a second driving signal PXIB6.

The first driving signals PXID0, PXID2, PXID4 and PXID6 and the second driving signals PXIB0, PXIB2, PXIB4 and PXIB6 may be generated by the row decoder 260 in FIG. 5 or a driving signal generator.

A voltage level of the negative voltage DVBB2 is smaller than a voltage level of the ground voltage VSS and a magnitude of the negative voltage VBB2 may be smaller than a magnitude of a negative voltage (for example, VBB2) which is used for driving a word-line in the conventional semiconductor memory device. In addition, a magnitude of the power supply voltage VPP may be smaller than a magnitude of a power supply voltage which is used for driving a word-line in the conventional semiconductor memory device. Each of the sub word-line drivers 420, 430, 440 and 450 may include at least one PMOS transistor and one or more NMOS transistors.

When a high electric field is applied to the gate of the PMOS transistor for a long time, the negative bias used in the semiconductor device becomes unstable according to a change in temperature. This is called negative bias temperature instability (NBTI), When NBTI occurs, a threshold voltage of the PMOS transistor increases, and performance of the semiconductor memory device may be degraded. Conversely, an increase in a threshold voltage of the NMOS transistors is referred to as positive bias temperature instability (PBTI) and, when PBTI occurs, the threshold voltage Vth of the NMOS transistor increases.

Because, the sub word-line decoder 410 applies the word-line enable signal NWEIB swinging between the power supply voltage VPP and the negative voltage DVBB2 to the sub word-line drivers 420, 430, 440 and 450 as mentioned above, NBTI occurring in the PMOS transistors in the sub word-line drivers 420, 430, 440 and 450 and PBTI occurring in the NMOS transistors in the sub word-line drivers 420, 430, 440 and 450 may be reduced. Therefore, a performance of the semiconductor memory device 200 may be enhanced.

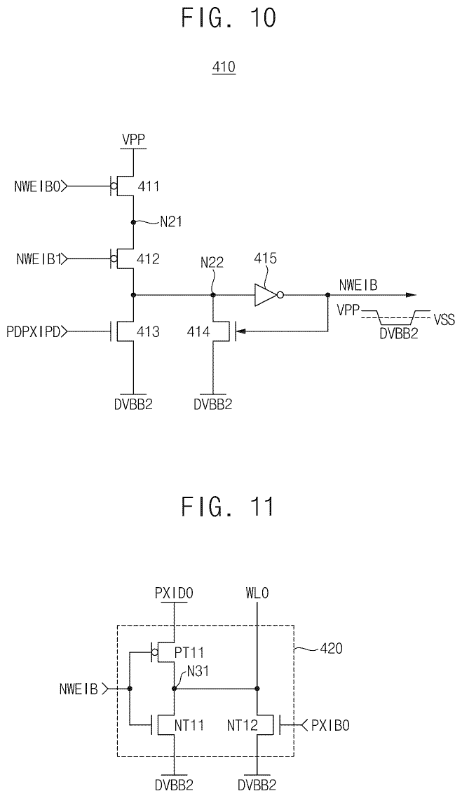

FIG. 10 is a circuit diagram illustrating an example of the sub word-line decoder in FIG. 9.

Referring to FIG. 10, the sub word-line decoder 410 may include a first PMOS transistor 411, a second PMOS transistor 412, a first NMOS transistor 413, a second NMOS transistor 414 and an inverter 415.

The first PMOS transistor 411 may be connected between the power supply voltage VPP and a first node N1 and may have a gate to receive the first intermediate word-line enable signal NWEIB0. The second PMOS transistor 412 may be connected between the first node N21 and a second node N22 and may have a gate to receive the second intermediate word-line enable signal NWEIB1.

The first NMOS transistor 413 may be connected between the second node N22 and the negative voltage DVBB2 and may have a gate to receive a block access signal PDPXIPD. The second NMOS transistor 414 may be connected between the second node N22 and the negative voltage DVBB2 in parallel with the first NMOS transistor 413 and may have a gate to receive the word-line enable signal NWEIB.

The inverter 415 may output the word-line enable signal NWEIB swinging between the power supply voltage VPP and the negative voltage DVBB2 by inverting a logic level (e.g., a voltage level) at the second node N22.

When each of the first intermediate word-line enable signal NWEIB0, the second intermediate word-line enable signal NWEIB1 and the block access signal PDPXIPD has a voltage level of the power supply voltage VPP, the first PMOS transistor 411 and the second PMOS transistor 412 are turned-off, the first NMOS transistor 413 is turned-on, and the second node N22 is driven with a voltage level of the negative voltage DVBB2. The inverter 415 may output the word-line enable signal NWEIB having a voltage level of the power supply voltage VPP by inverting a voltage level of the negative voltage DVBB2 at the second node N22. That is, based on the each of the first intermediate word-line enable signal NWEIB0, the second intermediate word-line enable signal NWEIB1 and the block access signal PDPXIPD having a voltage level of the power supply voltage VPP, the inverter 415 may output the word-line enable signal NWEIB having a voltage level of the power supply voltage VPP. In addition, based on the word-line enable signal NWEIB having a voltage level of the power supply voltage VPP, the second NMOS transistor 414 may be turned on and provide an additional current path between the second node N22 and the negative voltage DVBB2.

When each of the first intermediate word-line enable signal NWEIB0, the second intermediate word-line enable signal NWEIB1 and the block access signal PDPXIPD has a voltage level of the ground voltage VSS, the first PMOS transistor 411 and the second PMOS transistor 412 are turned-on, the first NMOS transistor 413 is turned-off, and the second node N22 is driven with a voltage level of the power supply voltage VPP. The inverter 415 may output the word-line enable signal NWEIB having a voltage level of the negative voltage DVBB2 by inverting a voltage level of the power supply voltage VPP at the second node N22. That is, based on the each of the first intermediate word-line enable signal NWEIB0, the second intermediate word-line enable signal NWEIB1 and the block access signal PDPXIPD having a voltage level of the ground voltage VSS, the inverter 415 may output the word-line enable signal NWEIB having a voltage level of the negative voltage DVBB2. In addition, based on the word-line enable signal NWEIB having a voltage level of the negative voltage DVBB2, the second NMOS transistor 414 may be turned off and cut off a current path between the second node N22 and the negative voltage DVBB2.

Although not illustrated, the inverter 415 may be supplied with the power supply voltage VPP and the negative voltage DVBB2.

FIG. 11 is a circuit diagram illustrating an example sub word-line driver of the sub word-line drivers in FIG. 9.

Although, a configuration of the sub word-line driver 420 is illustrated for convenience of explanation in FIG. 11, each configuration of the sub word-line drivers 430, 440 and 450 may be substantially the same as the configuration of the sub word-line driver 420.

Referring to FIG. 11, the sub word-line driver 420 may include a PMOS transistor PT11, a first NMOS transistor NT11 and a second NMOS transistor NT12.

The PMOS transistor PT11 may be connected between first (power) terminal receiving the first driving signal PXID0 and a first node N31 and may have a gate to receive the word-line enable signal NWEIB.

The first NMOS transistor NT11 may be connected between the first node N31 coupled to the word-line WL0 and the negative voltage DVBB2 and may have a gate to receive the word-line enable signal NWEIB. The second NMOS transistor NT12 may be connected between the first node N31 coupled to the word-line WL0 and the negative voltage DVBB2 in parallel with the first NMOS transistor NT11 and may have a gate to receive the second driving signal PXIB0. The first driving signal PXID0 and the second driving signal PXIB0 may be complementary to each other.

Based on the word-line enable signal NWEIB having a voltage level of the power supply voltage VPP, the PMOS transistor PT11 may be turned-off and may cut off a current path from the first terminal and the first node N31. Based on each of the word-line enable signal NWEIB and the second driving signal PXIB0 having a voltage level of the power supply voltage VPP, the first NMOS transistor NT11 and the second NMOS transistor NT12 may be turned-on and may drive the word-line WL0 with a voltage level of the negative voltage DVBB2.

Based on the first driving signal PXID0 having a voltage level of the power supply voltage VPP and the word-line enable signal NWEIB having a voltage level of the negative voltage DVBB2, the PMOS transistor PT11 may be turned-on, may supply the power supply voltage VPP to the first node N31, and may drive the word-line WL with a voltage level of the power supply voltage VPP. Based on the word-line enable signal NWEIB having a voltage level of the negative voltage DVBB2, the first NMOS transistor NT11 may be turned-off and may cut-off a first current path from the first node N31 to the negative voltage DVBB2. Based on the second driving signal PXIB0 having a voltage level of the ground voltage VSS, the second NMOS transistor NT12 may be turned-off and may cut-off a second current path from the first node N31 to the negative voltage DVBB2.

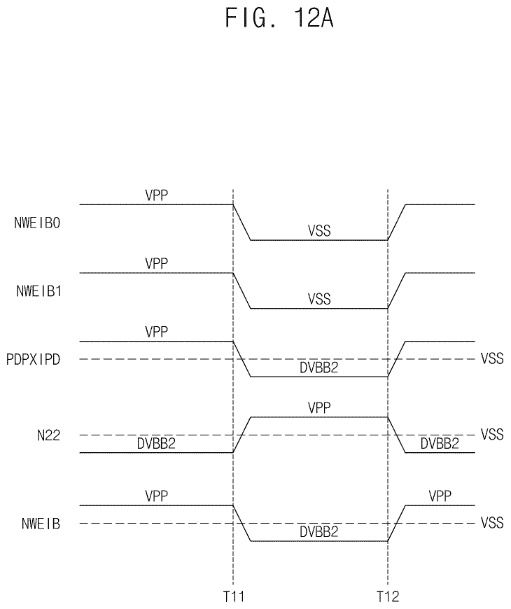

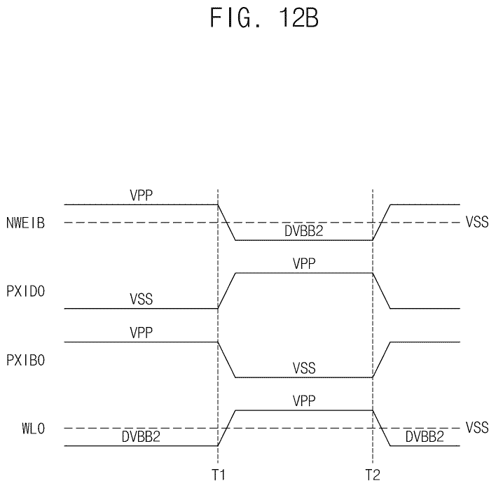

FIG. 12A is a waveform diagram illustrating an example of an operation of the sub word-line decoder of FIG. 10.

Referring to FIGS. 10 and 12A, prior to a first time point T11, when each of the first intermediate word-line enable signal NWEIB0, the second intermediate word-line enable signal NWEIB1 and the block access signal PDPXIPD has a voltage level of the ground voltage VSS, the first PMOS transistor 411 and the second PMOS transistor 412 are turned-on, the first NMOS transistor 413 is turned-off, and the second node N22 is driven with a voltage level of the power supply voltage VPP. Therefore, the inverter 415 may output the word-line enable signal NWEIB having a voltage level of the power supply voltage VPP by inverting a voltage level of the negative voltage DVBB2 at the second node N22.

At the time point T11, when each of the first intermediate word-line enable signal NWEIB0, the second intermediate word-line enable signal NWEIB1 and the block access signal PDPXIPD transits to the ground voltage VSS, the first PMOS transistor 411 and the second PMOS transistor 412 are turned-on, the first NMOS transistor 413 is turned-off, and the second node N22 is driven with a voltage level of the power supply voltage VPP.

When each of the first intermediate word-line enable signal NWEIB0, the second intermediate word-line enable signal NWEIB1 and the block access signal PDPXIPD has a voltage level of the ground voltage VSS between the time point T11 and a time point T12, the first PMOS transistor 411 and the second PMOS transistor 412 are turned-on, the first NMOS transistor 413 is turned-off, and the second node N22 is driven with a voltage level of the power supply voltage VPP. Therefore, the inverter 415 may output the word-line enable signal NWEIB having a voltage level of the negative voltage DVBB2 by inverting a voltage level of the power supply voltage VPP at the second node N22. In addition, based on the word-line enable signal NWEIB having a voltage level of the negative voltage DVBB2, the second NMOS transistor 414 may be turned off and cut off a current path between the second node N22 and the negative voltage DVBB2.

Operation posterior to the time point T12 may be substantially the same as the operation prior to the time point T11.

FIG. 12B is a waveform diagram illustrating an example of an operation of the sub word-line driver of FIG. 11.

Referring to FIGS. 11 and 12B, the sub word-line driver 420 may drive the word-line WL0 with the power supply voltage VPP or the negative voltage DVBB2 based on the word-line enable signal NWEIB. For example, the word-line enable signal NWEIB may have a voltage level of the power supply voltage VPP, corresponding to a deactivated state, prior to a first time point T1 and may have a voltage level of the negative voltage DVBB2, corresponding to an activated state, between the first time point T1 and a second time point T2.

Prior to the first time point T1, the first driving signal PXID0 may have a logic low level (e.g., a voltage level of the ground voltage VSS) and the second driving signal PXIB0 may have a logic high level (e.g., a voltage level of the power supply voltage VPP).

When a memory cell is accessed, the word-line enable signal NWEIB and the first driving signal PXID0 corresponding to the memory cell may be activated. The sub word-line driver 420 may provide the power supply voltage (e.g., a boosted voltage) VPP provided by the first driving signal PXID, to the word-line WL0, as the word-line enable signal NWEIB is activated with a voltage level of the negative voltage DVBB2. Accordingly, the sub word-line driver 420 may drive the word-line WL0 with the power supply voltage VPP.

For example, when the word-line enable signal NWEIB is activated to a voltage level of the negative voltage DVBB2 at the first time point T1, the first driving signal PXID0 may transition to the power supply voltage VPP, and the second driving signal PXIB0 may transition to a logic low level, for example, the ground voltage VSS.

After the memory cell access operation is completed, the sub word-line driver 420 may drive the word-line WL0 with a voltage level of the negative voltage DVBB2.

For example, when the word-line enable signal NWEIB is deactivated to a voltage level of the power supply voltage VPP at the second time point T2, the first driving signal PXID0 may transition to the ground voltage VSS level, and the second driving signal PXIB0 may transition to a voltage level of the power supply voltage VPP. Accordingly, the word-line WL0 may be lowered to a voltage level of the negative voltage DVBB2.

The second NMOS transistor NT2 may maintain the word-line WL0 at the negative voltage DVBB2 posterior to the second time point T2.

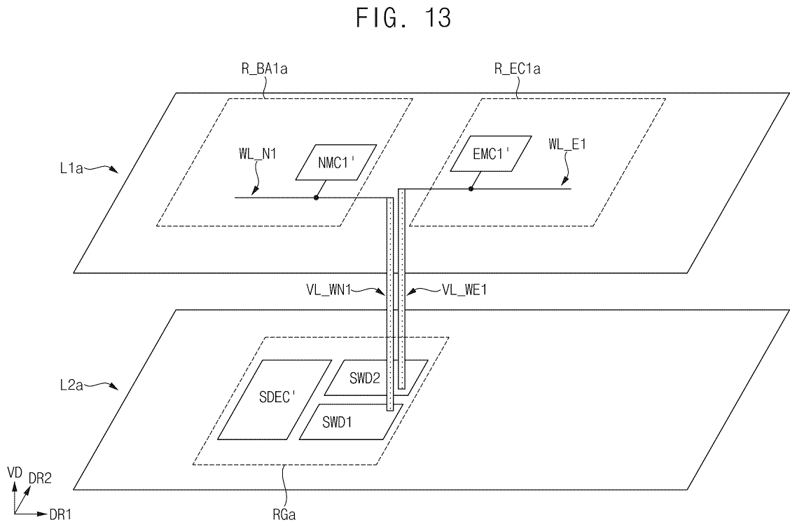

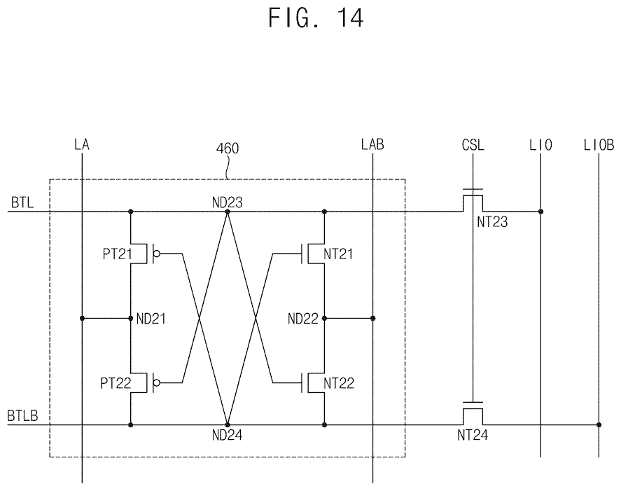

FIG. 13 is a diagram for describing an example of a semiconductor memory device of FIG. 2A.

Referring to FIG. 13, a first semiconductor layer L1a may include a first normal memory cell NMC1′ and a first ECC memory cell EMC1 and a second semiconductor layer L2a may include a sub word-line decoder SDEC′, a first sub word-line driver SWD1 and a second sub word-line driver SWD2 which are disposed in a region RGa.

FIG. 13 illustrates an example of a connection between the first normal memory cell NMC1′ and the first sub word-line driver SWD1 and a connection between the first ECC memory cell EMC1 and the second sub word-line driver SWD2.

The first normal memory cell NMC1′ in a first bank array region R_BA1a in the first semiconductor layer L1a and the first sub word-line driver SWD1 in the region RGa in the second semiconductor layer L2a may be electrically connected to each other through a vertical line (or wire) VL_WN1 extending in the vertical direction VD and a word-line WL_N1 extending in the first direction DR1.

The first ECC memory cell EMC1′ in a first ECC cell region R_EC1a in the first semiconductor layer L1a and the second sub word-line driver SWD2 in the region RGa in the second semiconductor layer L2a may be electrically connected to each other through a vertical line VL_WE1 extending in the vertical direction VD and a word-line WL_E1 extending in the first direction DR1.

In some implementations, each of the vertical lines VL_WN1 and VL_WE1 may include the bonding pads PD_L1 and PD_L2 and the contacts CT_L1 and CT_L2 in FIG. 2B.

The first normal memory cell NMC1′, the first ECC memory cell EMC1′ and the sub word-line drivers SWD1 and SWD2 may be included in the normal memory cells NMC, the ECC memory cells EMC and the sub word-line drivers SWD in FIG. 2B, respectively. The sub word-line drivers SWD1 and SWD2 may provide the first normal memory cell NMC1′ and the first ECC memory cell EMC1′ with the word-line enable signal NWEIB swinging between the power supply voltage and the negative voltage through the vertical lines VL_WN1 and VL_WE1.

FIG. 14 is a circuit diagram illustrating an example of the bit-line sense amplifier in FIG. 3A or in FIG. 3B.

Referring to FIG. 14, a bit-line sense amplifier 460 may be connected to the bit-line BL, and may have a circuit structure for driving the bit-line BTL. For example, the bit-line sense amplifier 460 may include transistors PT21, PT22, NT21 and NT22 that are connected to a control line LA and a complementary control line LAB through nodes ND21 and ND22, and are connected to the bit-line BTL and a complementary bit-line BTLB through nodes ND23 and ND24.

The transistor PT21 may be connected between the nodes ND23 and ND21, and may have a gate connected to the node ND24. The transistor PT22 may be connected between the nodes ND21 and ND24, and may have a gate connected to the node ND23. The transistor NT21 may be connected between the nodes ND23 and ND22, and may have a gate connected to the node ND24. The transistor NT22 may be connected between the nodes ND22 and ND24, and may have a gate connected to the node ND23. Depending on operations of turning on and/or off the transistors PT21, PT22, NT21 and NT22 included in the bit-line sense amplifier 460, various operations for the bit-line BTL, such as a precharge operation, an offset cancellation operation, a charge sharing operations, developing and sensing operations, etc., may be performed.

In addition, the bit-line BTL and the complementary bit-line BTLB may be connected to a local I/O line LIO and a complementary local I/O line LIOB through transistors NT23 and NT24, respectively. Gates of the transistors NT23 and NT24 may be connected to a column selection line CSL. When the transistors NT23 and NT24 are turned on, sensed data may be output.

In some implementations, each of the transistors PT21 and PT22 may be a PMOS transistor, and each of the transistors NT21, NT22, NT23 and NT24 may be an NMOS transistor.

However, example implementations are not limited thereto, and the bit-line sense amplifier is not limited to the structure illustrated in FIG. 14.

FIGS. 15 and 16 are perspective views of an example of a semiconductor memory device. The descriptions repeated with or overlapping with descriptions of FIG. 1 will be omitted in the interest of brevity.

Referring to FIG. 15, a semiconductor memory device 100c may include a first semiconductor layer L1, a second semiconductor layer L2 and a third semiconductor layer L3. An example of FIG. 15 may be substantially the same as the example of FIG. 1, except that the semiconductor memory device 100c further includes the third semiconductor layer L3.

The first semiconductor layer L1, the second semiconductor layer L2 and the third semiconductor layer L3 are disposed or stacked in the vertical direction VD. Although FIG. 15 illustrates an example where the first semiconductor layer L1 and the third semiconductor layer L3 are disposed on and below the second semiconductor layer L2, respectively, example implementations are not limited thereto. For example, both the first and third semiconductor layers L1 and L3 may be disposed on or below the second semiconductor layer L2.

As with the first semiconductor layer L1, the third semiconductor layer L3 may include a memory cell array MCA2, and may be referred to as a memory cell region or a cell wafer. For example, a memory cell array MCA1 included in the first semiconductor layer L1 may be referred to as a first memory cell array, and the memory cell array MCA2 included in the third semiconductor layer L3 may be referred to as a second memory cell array.

Each of the memory cell arrays MCA1 and MCA2 of the first and third semiconductor layers L1 and L3 may include the plurality of normal memory cells NMC and the plurality of ECC memory cells EMC, respectively. The plurality of ECC memory cells EMC in the first and third semiconductor layers L1 and L3 and the sub word-line decoder SDEC and the sub word-line drivers SWD in the second semiconductor layer L2 may be arranged to partially and/or completely overlap in a plan view or on a plane.

Referring to FIG. 16, a semiconductor memory device 100d may include a first semiconductor layer L1, a second semiconductor layer L2 and a fourth semiconductor layer L4. An example of FIG. 16 may be substantially the same as the example of FIG. 1, except that the semiconductor memory device 100d further includes the fourth semiconductor layer L4.

The first semiconductor layer L1, the second semiconductor layer L2 and the fourth semiconductor layer L4 are disposed or stacked in the vertical direction VD. Although FIG. 16 illustrates an example where the fourth semiconductor layer L4 and the second semiconductor layer L2 are disposed on and below the first semiconductor layer L1, respectively, example implementations are not limited thereto. For example, both the second and fourth semiconductor layers L2 and L4 may be disposed on or below the first semiconductor layer L1.

As with the second semiconductor layer L2, the fourth semiconductor layer L4 may include a peripheral circuit PCKT2, and may be referred to as a peripheral circuit region or a peripheral wafer. For example, a peripheral circuit PCKT1 included in the second semiconductor layer L2 may be referred to as a first peripheral circuit, and the peripheral circuit PCKT2 included in the fourth semiconductor layer L4 may be referred to as a second peripheral circuit.

Each of the peripheral circuits PCKT1 and PCKT2 of the second and fourth semiconductor layers L2 and L4 may include the sub word-line decoder SDEC and the sub word-line drivers SWD, respectively. The plurality of normal memory cells NMC and the plurality of ECC memory cells EMC in the first semiconductor layer L1 and sub word-line decoder SDEC and the sub word-line drivers SWD in the second and fourth semiconductor layers L2 and L4 may be arranged to partially and/or completely overlap in a plan view or on a plane.

Although not illustrated in detail, a memory device may include four or more semiconductor layers that are stacked.

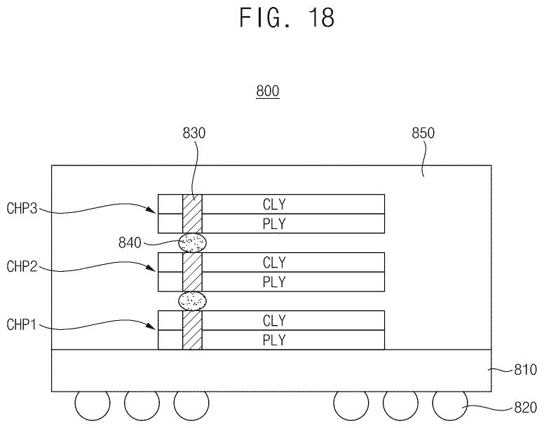

FIGS. 17 and 18 are cross-sectional views of an example of a memory package.

Referring to FIG. 17, a memory package 700 includes a base substrate 710 and a plurality of memory chips CHP1, CHP2 and CHP3 stacked on the base substrate 710.

Each of the memory chips CHP1, CHP2 and CHP3 may include a memory cell layer CLY and a peripheral circuit layer PLY, and may further include a plurality of I/O pads IOPAD. The memory cell layer CLY and the peripheral circuit layer PLY may correspond to the first semiconductor layer L1 and the second semiconductor layer L2 described with reference to FIG. 1, respectively, and further may include said elements described herein to be included in the first semiconductor layer L1 and the second semiconductor layer L2, respectively, according to any of the example implementations described herein. Each of the memory chips CHP1, CHP2 and CHP3 may include the semiconductor memory device, and may be implemented such that the memory cells and the sub word-line decoder and the sub word-line drivers included in different semiconductor layers are arranged to partially and/or completely overlap in a plan view or on a plane.

In some implementations, the memory chips CHP1, CHP2 and CHP3 may be stacked on the base substrate 710 such that a surface on which the plurality of I/O pads IOPAD are formed faces upwards. In some implementations, with respect to each of the memory chips CHP1, CHP2 and CHP3, the plurality of I/O pads IOPAD may be arranged near one side of the semiconductor substrate. As such, the memory chips CHP1, CHP2 and CHP3 may be stacked scalariformly, that is, in a step shape, such that the plurality of I/O pads IOPAD of each memory chip may be exposed. In such stacked state, the memory chips CHP1, CHP2 and CHP3 may be electrically connected to the base substrate 710 through a plurality of bonding wires BW.

The stacked memory chips CHP1, CHP2 and CHP3 and the plurality of bonding wires BW may be fixed by a sealing member 740, and adhesive members 730 may intervene between the base substrate 710 and the memory chips CHP1 to CHP3. Conductive bumps 720 may be formed on a bottom surface of the base substrate 710 for electrical connections to an external device.

Referring to FIG. 18, a memory package 800 includes a base substrate 810 and the plurality of memory chips CHP1, CHP2 and CHP3 stacked on the base substrate 810. The descriptions repeated with or overlapping with descriptions of FIG. 17 will be omitted in the interest of brevity.

Each of the memory chips CHP1, CHP2 and CHP3 may include the memory cell layer CLY and the peripheral circuit layer PLY, and may further include a plurality of through silicon vias (TSVs) 830.

In some implementations, with respect to each of the memory chips CHP1, CHP2 and CHP3, the plurality of TSVs 830 may be arranged at the same locations in each memory chip. As such, the memory chips CHP1, CHP2 and CHP3 may be stacked such that the plurality of TSVs 830 of each memory chip may be completely overlapped (e.g., arrangements of the plurality of TSVs 830 may be perfectly matched in the memory chips CHP1 to CHP3). In such stacked state, the memory chips CHP1, CHP2 and CHP3 may be electrically connected to one another and the base substrate 810 through the plurality of TSVs 830 and conductive material 840.

Conductive bumps 820 and a sealing member 850 may be substantially the same as the conductive bumps 720 and the sealing member 740 in FIG. 17.

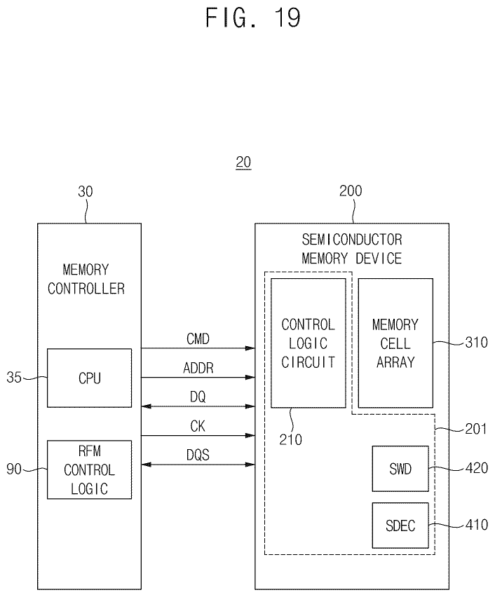

FIG. 19 is a block diagram illustrating an example of a memory system.

Referring to FIG. 19, a memory system 20 may include a memory controller 30 and a semiconductor memory device 200.

The memory controller 30 may control overall operation of the memory system 20. The memory controller 30 may control overall data exchange between an external host and the semiconductor memory device 200. For example, the memory controller 30 may write data in the semiconductor memory device 200 or read data from the semiconductor memory device 200 in response to request from the host.

In addition, the memory controller 30 may issue operation commands to the semiconductor memory device 200 for controlling the semiconductor memory device 200. In some implementations, the semiconductor memory device 200 is a memory device including dynamic memory cells such as a dynamic random access memory (DRAM), double data rate (DDR) synchronous DRAM (SDRAM), a low power (LP) DDR SDRAM or the like.

The memory controller 30 may transmit a clock signal CK (the clock signal CK may be referred to a command clock signal), a command CMD, and an address (signal) ADDR to the semiconductor memory device 200. Herein, for convenience of description, the terms of a clock signal CK, a command CMD, and an address ADDR and the terms of clock signals CK, commands CMD, and addresses ADDR may be used interchangeably. The memory controller 30 may transmit a data strobe signal DQS to the semiconductor memory device 200 when the memory controller 30 writes data signal DQ in the semiconductor memory device 200. The semiconductor memory device 200 may transmit a data strobe signal DQS to the memory controller 30 when the memory controller 30 reads data signal DQ from the semiconductor memory device 200. The address ADDR may be accompanied by the command CMD and the address ADDR may be referred to as an access address.

The memory controller 30 may include a central processing unit (CPU) 35 that controls overall operation of the memory controller 30 and a refresh management (RFM) control logic 90 that generates a refresh management command associated with a row hammer of the plurality of memory cell rows of the semiconductor memory device 200.

The semiconductor memory device 200 may include a memory cell array 310 that stores the data signal DQ and a peripheral circuit 201. The peripheral circuit 201 may include a control logic circuit 210, a sub word-line decoder 410 and a sub word-line driver 420. The sub word-line decoder 410 and the sub word-line driver 420 may be under the memory cell array 310.

The control logic circuit 210 may control operations of the semiconductor memory device 200. The memory cell array 310 may include a plurality of memory cell rows and each of the memory cell rows may include a plurality of (volatile) memory cells.

As described above, the sub word-line decoder 410 may generate a word-line enable signal swinging between a power supply voltage and a negative voltage by decoding a first intermediate word-line enable signal and a second intermediate word-line enable signal, each of which swings between the power supply voltage and a ground voltage and may apply the word-line enable signal to the sub word-line driver 420. The sub word-line driver 420 may drive a corresponding word-line with the power supply voltage or the negative voltage.

Therefore, because the sub word-line driver 420 is under the memory cell array 310, the semiconductor memory device 200 may reduce a chip size and wires associated with transferring the word-line enable signal. In addition, a voltage level of each of the power supply voltage and the negative voltage is smaller than each voltage level of the conventional power supply voltage and the conventional negative voltage, NBTI occurring in the PMOS transistors in the sub word-line driver 420 and PBTI occurring in the NMOS transistors in the sub word-line driver 420 may be reduced.

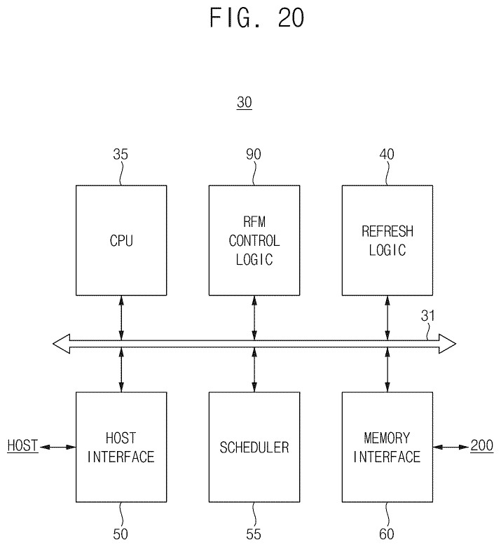

FIG. 20 is a block diagram illustrating an example of the memory controller in FIG. 19.

Referring to FIG. 20, the memory controller 30 may include the CPU 35, the RFM control logic 90, a refresh logic 40, a host interface 50, a scheduler 55 and a memory interface 60 which are connected to each other through a bus 31.

The CPU 35 may control overall operation of the memory controller 30. The CPU 35 may control the RFM control logic 90, the refresh logic 40, the host interface 50, the scheduler 55 and the memory interface 60 through the bus 31.

The refresh logic 40 may generate auto refresh command for refreshing memory cells of the plurality of memory cell rows based on a refresh interval of the semiconductor memory device 200.

The host interface 50 may perform interfacing with a host. The memory interface 60 may perform interfacing with the semiconductor memory device 200.

The scheduler 55 may manage scheduling and transmission of sequences of commands generated in the memory controller 30. The scheduler 55 may transmit an auto refresh command and the refresh management command to the semiconductor memory device 200 via the memory interface 60.

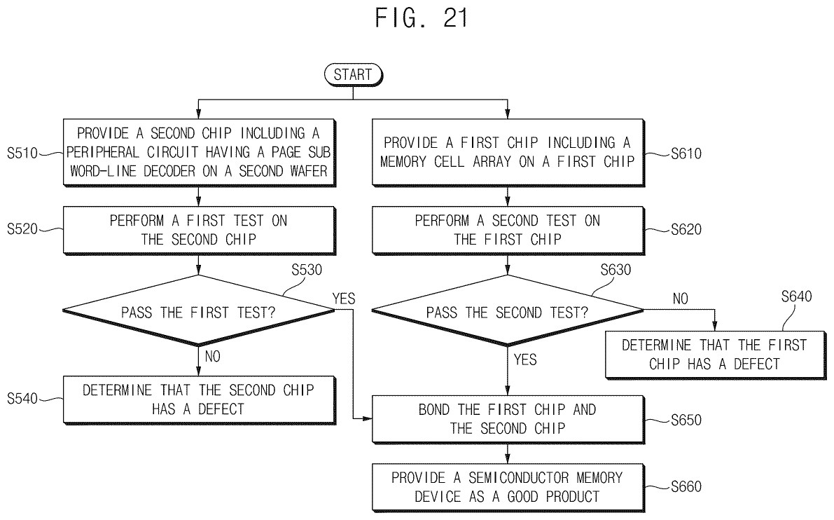

FIG. 21 is a flow chart illustrating an example of a method of manufacturing a semiconductor memory device.

Manufacturing method of FIG. 21 may be applied to manufacturing the semiconductor memory device 100 of FIG. 1.

Referring to FIG. 21, there is provided a method of manufacturing a semiconductor memory device including a first chip and a second chip. The first chip includes a memory cell region and is provided on a first wafer and the second chip includes a peripheral circuit region having a sub word-line decoder and is provided on a second wafer different from the first wafer.

According to the method, a second chip including a peripheral circuit region having a sub word-line decoder is formed (provided) on the second wafer (operation S510). A first test is performed on the second chip (operation S520). It is determined whether the second chip passes the first test based on a result of the first test (operation S530). When the second chip does not pass the first test (NO in operation S530), the second chip is determined as to have a defect (operation S540).

A first chip including a memory cell region is formed (provided) on the first wafer (operation S610) separately from forming and testing the second chip (operation S520). A second test is performed on the first chip (operation S620). It is determined whether the first chip passes the second test based on a result of the second test (operation S630). When the first chip does not pass the second test (NO in operation S630), the first chip is determined as to have a defect (operation S640).

When the second chip passes the first test (YES in operation S520) and the first chip does pass the second test (YES in operation S630), the first chip and the second chip are bonded (operation S650) and the semiconductor memory device is provided as a good product (operation S660).

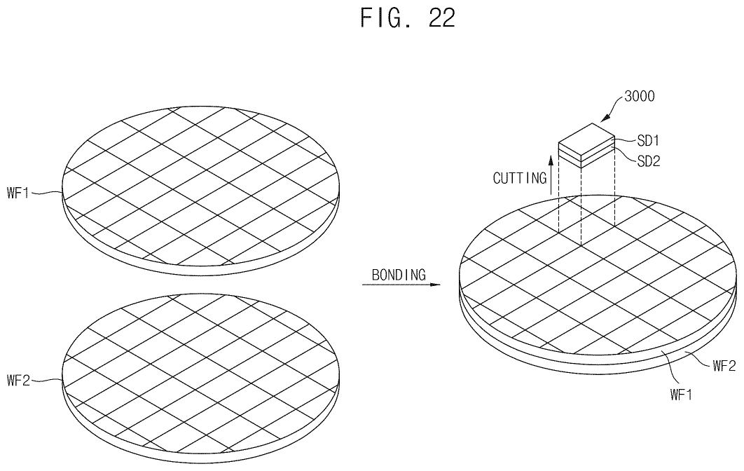

FIG. 22 is a diagram illustrating an example of a manufacturing process of a semiconductor device.

Referring to FIG. 22, respective integrated circuits may be formed on a first wafer WF1 and a second wafer WF2. The memory cell array may be formed in the first wafer WF1, and the peripheral circuits may be formed in the second wafer WF2.

After the various integrated circuits have been respectively formed on the first and second wafers WF1 and WF2, the first wafer WF1 and the second wafer WF2 may be bonded together. The bonded wafers WF1 and WF2 may then be cut (or divided) into separate chips, in which each chip corresponds to a semiconductor device such as, for example, a semiconductor memory device 3000, including a first semiconductor die SD1 and a second semiconductor die SD2 that are stacked vertically (e.g., the first semiconductor die SD1 is stacked on the second semiconductor die SD2, etc.). Each cut portion of the first wafer WF1 corresponds to the first semiconductor die SD1, and each cut portion of the second wafer WF2 corresponds to the second semiconductor die SD2. For example, the semiconductor memory device 3000 in FIG. 22 may be manufactured based on the manufacturing process of FIG. 21.

The example implementations may be applied to various electronic devices and systems that include the semiconductor memory devices. For example, the example implementations may be applied to systems such as a personal computer (PC), a server computer, a data center, a workstation, a mobile phone, a smart phone, a tablet computer, a laptop computer, a personal digital assistant (PDA), a portable multimedia player (PMP), a digital camera, a portable game console, a music player, a camcorder, a video player, a navigation device, a wearable device, an internet of things (IoT) device, an internet of everything (IoE) device, an e-book reader, a virtual reality (VR) device, an augmented reality (AR) device, a robotic device, a drone, an automotive, etc.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example implementations and is not to be construed as limiting thereof. Although a few example implementations have been described, those skilled in the art will readily appreciate that many modifications are possible in the example implementations without materially departing from the novel teachings and advantages of the present disclosure. Accordingly, all such modifications are intended to be included within the scope of the present disclosure as defined in the claims.

What is claimed is:

1. A semiconductor memory device comprising:
a first semiconductor layer including
a memory cell array connected to a plurality of word-lines and a plurality of bit-lines, the memory cell array including a plurality of memory cells configured to store data, the plurality of word-lines extending in a first direction, the plurality of bit-lines extending in a second direction crossing the first direction; and
a second semiconductor layer under the first semiconductor layer in a third direction, the third direction being perpendicular to both the first direction and the second direction, the second semiconductor layer including
a peripheral circuit configured to control the memory cell array, the peripheral circuit including one or more sub word-line drivers and a sub word-line decoder,
wherein the one or more sub word-line drivers are configured to drive the plurality of word-lines,
wherein the sub word-line decoder is configured to apply a word-line enable signal to the one or more sub word-line drivers based on a first intermediate word-line enable signal and a second intermediate word-line enable signal, and
wherein in a plan view, the one or more sub word-line drivers and the sub word-line decoder are in a first region in the second semiconductor layer, the plurality of memory cells are in a memory region in the first semiconductor layer, and the memory region overlaps the first region.

2. The semiconductor memory device of claim 1, wherein each of the first intermediate word-line enable signal and the second intermediate word-line enable signal is configured to swing between a power supply voltage and a ground voltage, and
wherein the word-line enable signal is configured to swing between the power supply voltage and a negative voltage.

3. The semiconductor memory device of claim 1, wherein the sub word-line decoder is configured to generate the word-line enable signal based on decoding the first intermediate word-line enable signal and the second intermediate word-line enable signal,
wherein each of the first intermediate word-line enable signal and the second intermediate word-line enable signal is configured to swing between a power supply voltage and a ground voltage, and
wherein the word-line enable signal is configured to swing between the power supply voltage and a negative voltage.

4. The semiconductor memory device of claim 1, wherein the sub word-line decoder includes:
a first p-channel metal-oxide semiconductor (PMOS) transistor connected between a power supply voltage and a first node, the first PMOS transistor having a gate configured to receive the first intermediate word-line enable signal, the first intermediate word-line enable signal being configured to swing between the power supply voltage and a ground voltage;
a second PMOS transistor connected between the first node and a second node, the second PMOS transistor having a gate configured to receive the second intermediate word-line enable signal, the second intermediate word-line enable signal being configured to swing between the power supply voltage and the ground voltage;
a first n-channel metal-oxide semiconductor (NMOS) transistor connected between the second node and a negative voltage, the first NMOS transistor having a gate configured to receive a block access signal;
a second NMOS transistor connected between the second node and the negative voltage in parallel with the first NMOS transistor, the second NMOS transistor having a gate configured to receive the word-line enable signal; and
an inverter configured to output the word-line enable signal based on inverting a voltage level at the second node, the word-line enable signal being configured to swing between the power supply voltage and the negative voltage.

5. The semiconductor memory device of claim 4, wherein:
based on the first intermediate word-line enable signal having a voltage level of the power supply voltage, the second intermediate word-line enable signal having the voltage level of the power supply voltage, and the block access signal having the voltage level of the power supply voltage, the inverter is configured to invert a voltage level of the negative voltage at the second node so as to output the word-line enable signal having the voltage level of the power supply voltage; and
based on the first intermediate word-line enable signal having a voltage level of the ground voltage, the second intermediate word-line enable signal having the voltage level of the ground voltage, and the block access signal having the voltage level of the power supply voltage, the inverter is configured to invert the voltage level of the power supply voltage at the second node so as to output the word-line enable signal having the voltage level of the negative voltage.

6. The semiconductor memory device of claim 4, wherein,
based on the word-line enable signal having a voltage level of the power supply voltage, the second NMOS transistor is configured to provide an additional current path between the second node and the negative voltage.

7. The semiconductor memory device of claim 1, wherein each sub word-line driver of the one or more sub word-line drivers is configured to drive, based on the word-line enable signal, a first driving signal, and a second driving signal, a respective word-line among the plurality of word-lines with a power supply voltage or a negative voltage.

8. The semiconductor memory device of claim 7, wherein each sub word-line driver of the one or more sub word-line drivers includes:
a p-channel metal-oxide semiconductor (PMOS) transistor connected between a first terminal and a first node, the first terminal being configured to receive the first driving signal, the PMOS transistor having a gate configured to receive the word-line enable signal;
a first n-channel metal-oxide semiconductor (NMOS) transistor connected between the first node and the negative voltage, the first node being coupled to the respective word-line, the first NMOS transistor having a gate configured to receive the word-line enable signal; and
a second NMOS transistor connected between the first node and the negative voltage, the second NMOS transistor having a gate configured to receive the second driving signal.

9. The semiconductor memory device of claim 8, wherein:
based on the word-line enable signal having a voltage level of the power supply voltage, the PMOS transistor is configured to cut off a current path from the first terminal and the first node; and
based on the word-line enable signal having a voltage level of the power supply voltage and the second driving signal having the voltage level of the power supply voltage, the first NMOS transistor and the second NMOS transistor are configured to drive the respective word-line with a voltage level of the negative voltage.

10. The semiconductor memory device of claim 8, wherein:
based on the first driving signal having a voltage level of the power supply voltage and the word-line enable signal having a voltage level of the negative voltage, the PMOS transistor is configured to drive the respective word-line with a voltage level of the power supply voltage;
based on the word-line enable signal having the voltage level of the negative voltage, the first NMOS transistor is configured to cut-off a first current path from the first node to the negative voltage; and
based on the second driving signal having a voltage level of a ground voltage, the second NMOS transistor is configured to cut-off a second current path from the first node to the negative voltage.

11. The semiconductor memory device of claim 1, wherein each sub word-line driver of the one or more sub word-line drivers is electrically connected to a respective word-line among the plurality of word-lines through a vertical line extending in the third direction.

12. The semiconductor memory device of claim 1, wherein the peripheral circuit includes:
the first region comprising the sub word-line decoder and the one or more sub word-line drivers; and
a second region comprising a row decoder, wherein the second region is adjacent to the first region in the first direction, and the row decoder is configured to generate the first intermediate word-line enable signal and the second intermediate word-line enable signal based on a decoded row address.

13. The semiconductor memory device of claim 12, wherein the row decoder includes:
a first main word-line driver configured to generate the first intermediate word-line enable signal based on the decoded row address, a block access signal, and a block selection signal; and
a second main word-line driver configured to generate the second intermediate word-line enable signal based on the decoded row address, the block access signal, and the block selection signal.

14. The semiconductor memory device of claim 12, wherein a bit-line sense amplifier is disposed in the first region, and the bit-line sense amplifier is connected to a first bit-line and a first complementary bit-line among the plurality of bit-lines.

15. The semiconductor memory device of claim 12, wherein the one or more sub word-line drivers are disposed in a first side of the sub word-line decoder, and the first side extends in the second direction.

16. The semiconductor memory device of claim 12, wherein the one or more sub word-line drivers are disposed in a second side of the sub word-line decoder, and the second side extends in the second direction and opposite to a first side of the sub word-line decoder.

17. The semiconductor memory device of claim 1, wherein each memory cell of the plurality of memory cells includes a cell transistor and a cell capacitor.

18. The semiconductor memory device of claim 1,
wherein the first semiconductor layer includes a first bonding pad,
wherein the second semiconductor layer includes a second bonding pad electrically connected to the first bonding pad, and
wherein the first semiconductor layer and the second semiconductor layer are electrically connected in the third direction through the first bonding pad and the second bonding pad.

19. A memory package comprising
a base substrate, and
a plurality of memory chips stacked on the base substrate,
wherein each memory chip of the plurality of memory chips includes
a first semiconductor layer comprising a memory cell array connected to a plurality of word-lines and a plurality of bit-lines, the memory cell array including a plurality of memory cells configured to store data, wherein the plurality of word-lines extend in a first direction and the plurality of bit-lines extend in a second direction crossing the first direction; and
a second semiconductor layer under the first semiconductor layer in a third direction, the third direction being perpendicular to both the first direction and the second direction, wherein the second semiconductor layer comprises a peripheral circuit configured to control the memory cell array, the peripheral circuit including one or more sub word-line drivers and a sub word-line decoder,
wherein the one or more sub word-line drivers are configured to drive the plurality of word-lines,
wherein the sub word-line decoder is configured to apply a word-line enable signal to the one or more sub word-line drivers based on a first intermediate word-line enable signal and a second intermediate word-line enable signal, and
wherein in a plan view, the one or more sub word-line drivers and the sub word-line decoder are in a first region in the second semiconductor layer, the plurality of memory cells are in a memory region in the first semiconductor layer, and the memory region overlaps the first region.

20. A semiconductor memory device comprising:
a first semiconductor layer comprising a memory cell array connected to a plurality of word-lines and a plurality of bit-lines, the memory cell array including a plurality of memory cells configured to store data, the plurality of word-lines extending in a first direction, the plurality of bit-lines extending in a second direction crossing the first direction; and
a second semiconductor layer under the first semiconductor layer in a third direction, the third direction being perpendicular to both the first direction and the second direction, the second semiconductor layer comprising a peripheral circuit configured to control the memory cell array, the peripheral circuit including one or more sub word-line drivers and a sub word-line decoder, wherein the one or more sub word-line drivers are configured to drive the plurality of word-lines, wherein the sub word-line decoder is configured to apply a word-line enable signal to the one or more sub word-line drivers based on a first intermediate word-line enable signal and a second intermediate word-line enable signal, wherein in a plan view, the one or more sub word-line drivers and the sub word-line decoder are in a first region in the second semiconductor layer, the plurality of memory cells are in a memory region in the first semiconductor layer, and the memory region overlaps the first region,
wherein the sub word-line decoder is configured to generate the word-line enable signal based on the first intermediate word-line enable signal and the second intermediate word-line enable signal,
wherein each intermediate word-line enable signal of the first intermediate word-line enable signal and the second intermediate word-line enable signal is configured to swing between a power supply voltage and a ground voltage, and
wherein the word-line enable signal is configured to swing between the power supply voltage and a negative voltage.
